(19) United States
(12) Patent Application Publication
(10) Pub. No.: US 2026/0018503 A1
(43) Pub. Date: Jan. 15, 2026

(54) SEMICONDUCTOR PACKAGES

(71) Applicant: SAMSUNG ELECTRONICS CO., LTD., Suwon-si (KR)

(72) Inventor: Junbyeong LEE, Suwon-si (KR)

(73) Assignee: SAMSUNG ELECTRONICS CO., LTD., Suwon-si (KR)

(21) Appl. No.: 19/016,413

(22) Filed: Jan. 10, 2025

(30) Foreign Application Priority Data
Jul. 11, 2024 (KR) 10-2024-0091933

(51) Int. Cl. H01L 23/498; H01L 23/538; H01L 25/07

(52) U.S. Cl. CPC H01L 23/49816; H01L 23/49894; H01L 23/5386; H01L 25/074; H01L 2225/0651; H01L 2225/06565

(57) ABSTRACT

A semiconductor package includes: a semiconductor chip; a package substrate below the semiconductor chip in a vertical direction; and a plurality of connection pads on a lower surface of the package substrate, wherein the plurality of connection pads include: a first group of connection pads having a first width, and a second group of connection pads having a second width smaller than the first width, and wherein the first group of connection pads are provided closer to an edge boundary of a contact surface between the semiconductor chip and the package substrate than the second group of connection pads.

### CROSS-REFERENCE TO RELATED APPLICATION

This application is based on and claims the benefit under 35 U.S.C. § 119 to Korean Patent Application No. 10-2024-0091933, filed on Jul. 11, 2024, in the Korean Intellectual Property Office, the disclosure of which is incorporated by reference herein in its entirety.

### BACKGROUND

### 1. Field

The disclosure relates to semiconductor packages.

### 2. Description of Related Art

With the development of the electronics industry, high functionality, high speed, and miniaturization of electronic components are demanded. In line with this trend, technical solutions have been researched to secure design freedom within a package substrate while improving reliability of the package substrate.

### SUMMARY

Provided is semiconductor packages having improved reliability.

According to an aspect of the disclosure, a semiconductor package includes: a plurality of semiconductor chips stacked vertically, and including a first semiconductor chip at a bottom in a vertical direction; a package substrate below the plurality of semiconductor chips, and including: a contact boundary defined by the first semiconductor chip, and a first region that is a ring-shaped region extending along the contact boundary with a predetermined width, a second region inside the first region, and a third region outside the first region; a plurality of connection pads on a lower surface of the package substrate; and a plurality of connection bumps below the plurality of connection pads, respectively, wherein the plurality of connection pads include: a first group of connection pads at least a portion of each of which is within the first region, and a second group of connection pads within the second region and the third region, and wherein a first width of the first group of connection pads is greater than a second width of the second group of connection pads.

According to an aspect of the disclosure, a semiconductor package includes: a semiconductor chip; a package substrate below the semiconductor chip in a vertical direction; and a plurality of connection pads on a lower surface of the package substrate, wherein the plurality of connection pads include: a first group of connection pads having a first width, and a second group of connection pads having a second width smaller than the first width, and wherein the first group of connection pads are provided closer to an edge boundary of a contact surface between the semiconductor chip and the package substrate than the second group of connection pads.

According to an aspect of the disclosure, a semiconductor package includes: a package substrate; a semiconductor chip on the package substrate, in a vertical direction; a plurality of connection pads on a lower surface of the package substrate, in the vertical direction; a plurality of connection bumps below the plurality of connection pads, respectively; and a protective layer covering at least portions of the plurality of connection pads and surrounding at least portions of the plurality of connection bumps, wherein the plurality of connection pads include: a first connection pad adjacent to an edge boundary of a contact surface between the semiconductor chip and the package substrate, and a second connection pad around the first connection pad, and wherein a first contact area between the first connection pad and the protective layer is larger than a second contact area between the second connection pad and the protective layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1A is a plan view illustrating a semiconductor package according to an example embodiment;

FIG. 1B is a cross-sectional view illustrating a semiconductor package according to an example embodiment;

FIG. 2 is a partially enlarged view illustrating a portion of a semiconductor package according to an example embodiment;

FIG. 3 is a cross-sectional view illustrating a portion of a semiconductor package of the related art;

FIG. 4 is a partially enlarged view illustrating a portion of a semiconductor package of the related art;

FIG. 5 is a partially enlarged view illustrating a portion of a semiconductor package according to an example embodiment;

FIG. 6 is a partially enlarged view illustrating a portion of a semiconductor package according to an example embodiment;

FIG. 7 is a partially enlarged view illustrating a portion of a semiconductor package according to an example embodiment;

FIG. 8 is a partially enlarged view illustrating a portion of a semiconductor package according to an example embodiment;

FIG. 9 is a cross-sectional view illustrating a semiconductor package according to an example embodiment;

FIG. 10 is a plan view illustrating a semiconductor package according to an example embodiment;

FIG. 11 is a plan view illustrating a semiconductor package according to an example embodiment;

FIG. 12 is a plan view illustrating a semiconductor package according to an example embodiment;

FIG. 13 is a plan view illustrating a semiconductor package according to an example embodiment;

FIG. 14 is a plan view illustrating a semiconductor package according to an example embodiment;

FIG. 15 is a plan view illustrating a semiconductor package according to an example embodiment;

FIG. 16A, FIG. 17A, FIG. 18A, and FIG. 19 are cross-sectional views illustrating a process sequence for describing a method of manufacturing a semiconductor package according to an example embodiment; and

FIG. 16B, FIG. 17B, and FIG. 18B are partially enlarged views illustrated according to a process sequence for describing a method of manufacturing a semiconductor package according to an example embodiment.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

Example embodiments will be described with reference to the accompanying drawings. Hereinafter, terms such as “on,” “upper portion,” “top surface,” “upper surface,” “below,” “lower portion” “lower surface,” “side,” “side surface,” and the like may be understood to refer to the drawings, except in cases in which they are separately designated by being indicated with drawing symbols. “Top” means a part located at the highest level of a certain configuration, and “bottom” means a part located at the lowest level of a certain configuration.

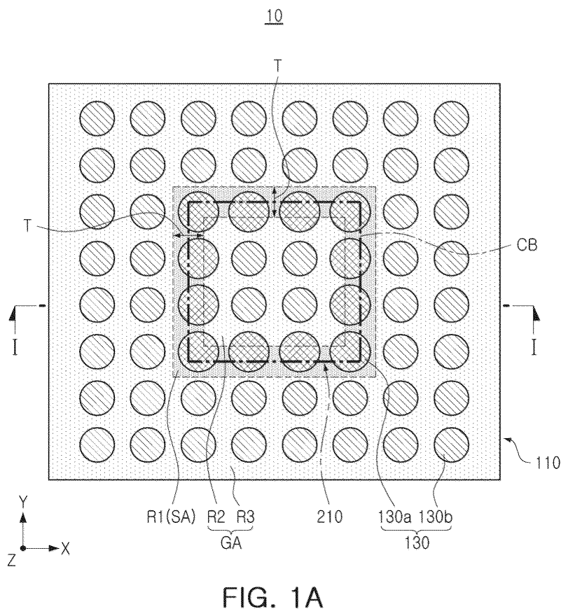

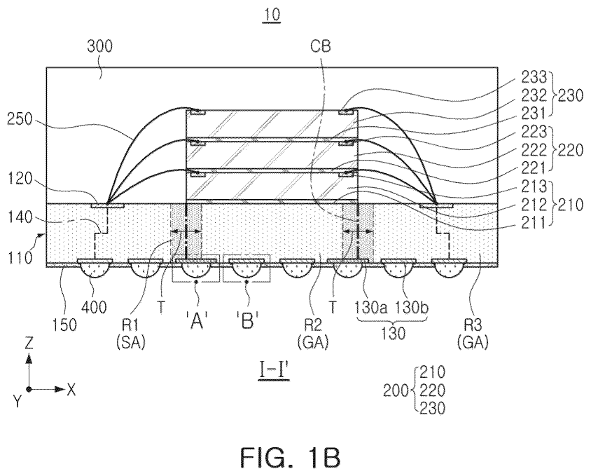

FIG. 1A is a plan view illustrating a semiconductor package 10 according to an example embodiment. FIG. 1B is a cross-sectional view illustrating a semiconductor package 10 according to an example embodiment. FIG. 1B illustrates an example of a cross-section cut along the cutting line I-I′ of the semiconductor package 10 of FIG. 1A.

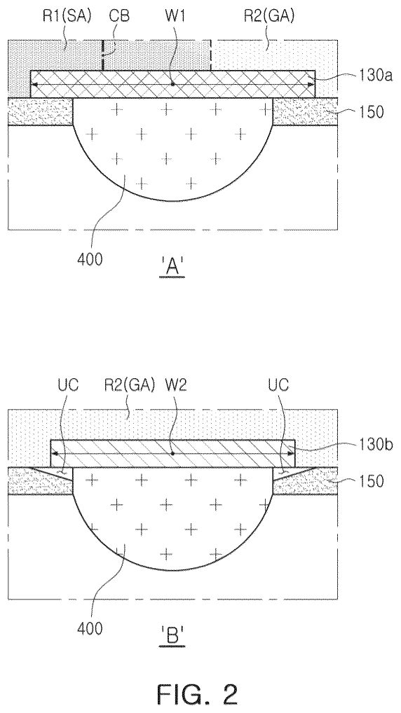

FIG. 2 is a partial enlargement view illustrating a part of a semiconductor package 10 according to an example embodiment. FIG. 2 illustrates an enlargement of the ‘A’ area and the ‘B’ area of FIG. 1B. The ‘B’ region of FIG. 2 illustrates an example of a second group of connection pads 130b disposed in the second region R2. The description referring to the ‘B’ region of FIG. 2 is applied to the second group of connection pads 130b disposed in the third region R3 as well as the second region R2.

Referring to FIGS. 1A to 2, the semiconductor package 10 may include a package substrate 110, a plurality of connection pads 130, a protective layer 150, and a plurality of semiconductor chips 200. As shown in FIG. 1B, the semiconductor package 10 may further include upper pads 120, a wiring circuit 140, connection wires 250, a encapsulant 300, and a plurality of connection bumps 400.

In an embodiment, the package substrate 110 is a support substrate on which a plurality of semiconductor chips 200 are mounted. The package substrate 110 may be a semiconductor package substrate including a printed circuit board PCB, a ceramic substrate, a glass substrate, a tape wiring substrate, or the like. For example, the package substrate 100 may be a one-sided printed circuit board one-sided PCB, a double-sided printed circuit board double-sided PCB, or a multi-layer printed circuit board multi-layer PCB. The package substrate 110 may include an insulating material protecting the wiring circuit 140, for example, a thermosetting resin such as an epoxy resin, a thermoplastic resin such as a polyimide, or a prepreg including an inorganic filler or/and glass fiber glass cloth, glass fabric, Ajinomoto Build-up Film ABF, Frame Retardant 4 FR4, or the like.

In an embodiment, the package substrate 110 may include a contact boundary CB, a first region R1, a second region R2, and a third region R3. These regions are not separate structures that are distinct from each other, and may be regions of the package substrate 110 defined by the first semiconductor chip 210 that is positioned at the bottom among the plurality of semiconductor chips 200. Even when only a single first semiconductor chip 210 is mounted on the package substrate 110, the contact boundary CB and the first to third regions R1, R2 and R3 of the package substrate 110 may likewise be defined by the first semiconductor chip 210. The first region R1 may be defined as a ring-shaped region that has a predetermined width T and extends along the contact boundary CB between the first semiconductor chip 210 and the package substrate 110.

In the disclosure, the contact boundary CB is defined as a portion overlapping with the edge boundary of the area where the first semiconductor chip 210 and the package substrate 110 come into contact. In the disclosure, the term ‘overlapping’ may indicate that there is a portion positioned on the same line in a direction perpendicular to the upper surface of the package substrate 110, for example, in the Z-direction.

The first region R1 may be defined based on the contact boundary CB. The first region R1 extends along the contact boundary CB. The contact boundary CB may be the center line of the first region R1. The first region R1 includes an inner side portion positioned on the inner side of the contact boundary CB and an outer side portion positioned on the outer side of the contact boundary CB. The first region R1 may have a predetermined width T.

In an example embodiment, the inner side portion and the outer side portion of the first region R1 may have substantially the same width. The first region R1 may be a vulnerable area SA where stress is aggravated by various peripheral configurations. In an example embodiment, the first region R1 may be defined as a region from 100 μm inside the contact boundary CB to 100 μm outside the contact boundary CB. In this case, the width T of the first region R1 may be defined as 200 μm. The width T of the first region R1 is not limited thereto and may vary depending on some example embodiments.

In an example embodiment, the first region R1 may be defined as a region from 150 μm inside the contact boundary CB to 150 μm outside the contact boundary CB, and the width T of the first region may be defined as 300 μm.

In an example embodiment, the first region R1 may be defined as a region from 50 μm inside the contact boundary CB to 50 μm outside the contact boundary CB, and the width T of the first region may be defined as 100 μm. In an example embodiment, the first region R1 is defined as a region from 200 μm inside the contact boundary CB to 200 μm outside the contact boundary CB, and the width T of the first region may be defined as 400 μm. The width T of the first region R1 defined as the vulnerable area SA is not limited to the above embodiments and may be variously modified according to the example embodiments.

In an example embodiment, the width of the first region R1 may be 150 μm to 250 μm. In an example embodiment, when the first semiconductor chip 210 has a rectangular parallelepiped shape, the contact boundary CB completely overlaps with the side surfaces of the first semiconductor chip 210, and therefore, the first region R1 may also be defined as a ring-shaped region extending along the side surfaces of the first semiconductor chip 210 with a predetermined width T.

The first region R1 may overlap with the side surfaces of the first semiconductor chip 210. The second region R2 may be a region located on the inner side of the first region R1, surrounded by the first region R1, and overlapping with the first semiconductor chip 210. The third region R3 may be a region surrounding the first region R1 on the outer side of the first region R1 and not overlapping with the first semiconductor chip 210. The second region R2 and the third region R3 may be general regions GA in which the stress is less aggravated than that of the first region R1, or in which the stress is relatively less affected by the stress, even if it is aggravated, on the reliability of the semiconductor package. As described above, the first to third regions R1, R2 and R3 of the package substrate 110 may be defined by the contact boundary CB of the first semiconductor chip 210 located at the bottom among the plurality of semiconductor chips 200. The width T of the first region R1 evaluated as the vulnerable area SA may be defined in various ways depending on some example embodiments.

The upper pads 120 may be disposed on the upper surface of the package substrate 110, for example, to be spaced apart from the plurality of semiconductor chips 200. In an embodiment, the upper pads 120 may be disposed on the upper surface of the third region R3 of the package substrate 110. In an embodiment, the upper pads 120 may be electrically connected to the plurality of semiconductor chips 200 through the connection wires 250. The upper pads 120 may include, for example, at least one metal material among aluminum (Al), copper (Cu), nickel (Ni), tungsten (W), platinum (Pt), and gold (Au), but are not limited thereto. The upper pads 120 may include more or less than the number illustrated in FIG. 1B.

A plurality of connection pads 130 may be disposed on the lower surface of the package substrate 110. The plurality of connection pads 130 are illustrated as having a circular planar shape, but are not limited thereto. For example, the planar shape of each of the plurality of connection pads 130 may be variously modified, such as a polygon, an oval, or the like.

In an embodiment, as illustrated in FIG. 1B, the plurality of connection pads 130 may include a first group of connection pads 130a that at least partially overlap with the first region R1, and a second group of connection pads 130b that do not overlap with the first region R1. For example, at least a portion of each of the first group of connection pads 130a may be disposed within the first region R1, and each of the second group of connection pads 130b may be disposed within the second region R2 and the third region R3.

The first connection pad 130a refers to an example embodiment of the ‘first group’ of the connection pads 130a, and the second connection pad 130b refers to an example embodiment of the ‘second group’ of the connection pads 130b. At least some of the first group of the connection pads 130a may be disposed to overlap with the second region R2 or the third region R3 at the same time. In an example embodiment, at least some of the first group of the connection pads 130a may be disposed to overlap with the contact boundary CB.

In an example embodiment, at least some of the first group of the connection pads 130a may be disposed to overlap with side surfaces of the first semiconductor chip 210. In an example embodiment, as illustrated in FIG. 1B, at least some of the first group of the connection pads 130a may be disposed to overlap with the first region R1 and the second region R2. In an example embodiment, unlike the illustrated embodiment, at least some of the first group of the connection pads 130a may be disposed to overlap the first region R1 and the third region R3.

The second group of the connection pads 130b may be disposed in the second region R2 and the third region R3 within a range that does not overlap the first region R1. The second group of the connection pads 130b disposed in the second region R2 may overlap the first semiconductor chip 210. The second group of the connection pads 130b disposed in the third region R3 may not overlap the first semiconductor chip 210.

As illustrated in FIG. 2, the first group of the connection pads 130a may have a first width W1, and the second group of the connection pads 130b may have a second width W2 smaller than the first width W1. The first width W1 and the second width W2 may refer to the maximum width of each connection pad in the direction parallel to the upper surface of the package substrate 110.

For example, when a plurality of connection pads 130 have a circular planar shape as illustrated, the first width W1 may refer to the diameter of the first group of the connection pads 130a, and the second width W2 may refer to the diameter of the second group of the connection pads 130b. The first group of the connection pads 130a having the first width W1 may be formed to have a wider contact area with the protective layer 150 than the second group of the connection pads 130b having the second width W2. At least a portion of the second group of the connection pads 130b may have a reduced contact area with the protective layer 150 due to an undercut UC that may be formed below the second group of the connection pads 130b, or may not make contact depending on some example embodiments.

Undercut UC refers to a space (or an area) between a plurality of connection pads 130 and the protective layer 150 that may be formed due to insufficient contact area or weakened adhesive strength between the protective layer 150 and the plurality of connection pads 130, which may reduce the reliability of the semiconductor package in some cases. The undercut UC may be formed during the manufacturing process of the semiconductor package, or even after completion. The formation of the undercut UC may be reduced or prevented under the first group of connection pads 130a having the first width W1. In an example embodiment, the undercut UC may not exist under the second group of connection pads 130b.

In an example embodiment, the first width W1 may be 1.05 to 1.15 times larger than the second width W2, but is not limited thereto.

In an example embodiment, when the second width W2 is about 450 μm, the first width W1 may be formed to be about 472.5 μm to 517.5 μm. In an example embodiment, the second width W2 may be 400 μm to 420 μm, and the first width W1 may be 420 μm to 483 μm. In an example embodiment, the second width W2 may be 420 μm to 440 μm, and the first width W1 may be 441 μm to 506 μm. In an example embodiment, the second width W2 may be 440 μm to 460 μm, and the first width W1 may be 462 μm to 529 μm. In an example embodiment, the second width W2 may be 460 μm to 480 μm, and the first width W1 may be 483 μm to 552 μm. In an example embodiment, the second width W2 may be 480 μm to 500 μm, and the first width W1 may be 504 μm to 575 μm. The above figures exemplify embodiments in which the first width W1 is 1.05 to 1.15 times longer than the second width W2, and the first width W1 and the second width W2 are not limited to the above embodiments. The first width W1 and the second width W2 may be variously modified in a range where the first width W1 is larger than the second width W2. The plurality of connection pads 130 may include, for example, at least one metal material among aluminum (Al), copper (Cu), nickel (Ni), tungsten (W), platinum (Pt), and gold Au, but are not limited thereto.

The plurality of connection pads 130 including the first group of connection pads 130a and the second group of connection pads 130b may include more or fewer than those illustrated. In a range where the first width W1 is larger than the second width W2, the relative sizes of the plurality of connection pads 130 with respect to the package substrate 110 may be variously modified. For example, the plurality of connection pads 130 may be disposed in greater numbers with a smaller width than illustrated, or conversely, in greater numbers with a larger width than illustrated.

In an embodiment, as shown in FIG. 1B, the wiring circuit 140 may electrically connect the upper pads 120 and the plurality of connection pads 130 within the package substrate 110. The wiring circuit 140 may include conductive patterns and conductive vias that form electrical connection paths. The wiring circuit 140 illustrated in FIG. 1B illustrates electrical connection paths formed by the conductive patterns and conductive vias, and is not intended to limit the plurality of connection pads 130 connected to the wiring circuit 140.

At least some of the plurality of connection pads 130 may be electrically connected to the upper pads 120 through the wiring circuit 140 according to the design intent. Some of the plurality of connection pads 130 may be dummy pads that are not electrically connected to the upper pads 120. The wiring circuit 140 may include at least one metal or an alloy of two or more metals selected from the group consisting of copper (Cu), aluminum (Al), nickel (Ni), silver (Ag), gold Au, platinum (Pt), tin (Sn), lead (Pb), titanium (Ti), chromium (Cr), palladium (Pd), indium (In), zinc (Zn), and carbon (C).

As illustrated in FIG. 1B, a protective layer 150 may be disposed to surround side surfaces of the plurality of connection bumps 400 below the package substrate 110. The protective layer 150 may cover a portion of the lower surfaces of the plurality of connection pads 130. The protective layer 150 may be in contact with at least a portion of the plurality of connection bumps 400. A contact area between the protective layer 150 and a first connection pad 130a, which is an example embodiment of the first group of connection pads 130a, may be larger than a contact area between the protective layer 150 and a second connection pad 130b, which is an example embodiment of the second group of connection pads 130b.

An undercut UC may be formed between the second connection pad 130b having a relatively small contact area and the protective layer 150. Depending on the size of the undercut UC, in an example embodiment, the second connection pad 130b may be spaced apart from the protective layer 150. Under the first connection pad 130a having a relatively large contact area, the undercut UC may be prevented, or even if formed, may be formed to be relatively small.

In an example embodiment, the undercut UC (under the second connection pad 130b) may further extend in the horizontal direction (for example, X-direction) and may exist between the second region R2 and the protective layer 150, or between the third region R3 and the protective layer 150. In an embodiment, the protective layer 150 may include a heat-conductive material that protects the package substrate 110 and the plurality of connection pads 130, for example, a thermosetting resin such as an epoxy resin, a thermoplastic resin such as a polyimide, or a prepreg including an inorganic filler or/and glass fiber Glass Fiber, Glass Cloth, Glass Fabric, ABF Ajinomoto Build-up Film, FR4 Frame Retardant 4, or the like.

The semiconductor package of the disclosure may prevent or reduce the formation of an undercut UC in the first region R1 by arranging the first group of connection pads 130a that at least partially overlap with the first region R1 defined as the vulnerable area SA to have a wider width than the second group of connection pads 130b that do not overlap with the first region R1, thereby improving the reliability of the semiconductor package. In addition, the second group of the connection pads 130b may have a smaller width than the first group of the connection pads 130a, thereby securing design freedom of the package substrate 110.

In an embodiment, a plurality of semiconductor chips 200 may be mounted on a substrate by a wire bonding or flip-chip bonding method. In an example embodiment, the plurality of semiconductor chips 200 may be stacked vertically in the Z-direction on the package substrate 110 and electrically connected to an upper pad 120 disposed on an upper surface of the package substrate 110 by connection wires 250.

The plurality of semiconductor chips 200 may include the first semiconductor chip 210, the second semiconductor chip 220, and the third semiconductor chip 230, but are not limited thereto. For example, the plurality of semiconductor chips 200 may include more or fewer semiconductor chips than those illustrated. For example, the plurality of semiconductor chips 200 may include two semiconductor chips, a first semiconductor chip 210 and a second semiconductor chip 220, or may include four or more semiconductor chips. In an example embodiment, the semiconductor package 10 may include only a single first semiconductor chip 210. In the disclosure, a description compatible with an embodiment in which only a single first semiconductor chip 210 is mounted among a description of a plurality of semiconductor chips 200 may be a comprehensive description of a description of a semiconductor package of an example embodiment in which a single first semiconductor chip 210 is mounted.

The semiconductor chip 210 of the disclosure may refer to the first semiconductor chip 210. The first semiconductor chip 210 may define a contact boundary CB of the package substrate 110 and first to third regions R1, R2 and R3. The plurality of semiconductor chips 200 may include bonding layers 211, 221 and 231 disposed on lower surfaces thereof and connection pads 213, 223 and 233 disposed on upper surfaces thereof.

The plurality of semiconductor chips 200 may be fixed by respective bonding layers 211, 221 and 231. The plurality of semiconductor chips 200 may be connected to the package substrate 110 through connection wires 250 connected to respective connection pads 213, 223 and 233. Each of the plurality of semiconductor chips 200 may be a memory chip including a memory circuit, such as a volatile memory, such as a dynamic RAM (DRAM), a static RAM (SRAM), and the like, and a nonvolatile memory, such as a phase change RAM (PRAM), a magnetic RAM (MRAM), a resistive RAM (RRAM), and a flash memory.

In an example embodiment, at least some of the plurality of semiconductor chips 200 may be logic chips including logic circuits such as a central processor (CPU), a graphics processor (GPU), a field programmable gate array (FPGA), an application processor (AP), a digital signal processor, an encryption processor, a microprocessor, a microcontroller, an analog-to-digital converter, an application-specific IC (ASIC), and the like. The plurality of semiconductor chips 200 may be the same or different types of semiconductor chips.

In an embodiment, the encapsulant 300 may cover at least a portion of the plurality of semiconductor chips 200 and the connection wires 250 on the package substrate 110. The encapsulant 300 may physically and chemically protect the plurality of semiconductor chips 200 and the connection wires 250, which are components on the package substrate 110, from the outside. The encapsulant 300 may include, for example, a thermosetting resin such as an epoxy resin, a thermoplastic resin such as a polyimide, or a prepreg, ABF, FR-4, BT, Epoxy Molding Compound (EMC). For example, the encapsulant 300 may include EMC. In an example embodiment, the encapsulant 300 may be omitted.

A plurality of connection bumps 400 may be disposed below the plurality of connection pads 130, respectively. The plurality of connection bumps 400 may be electrically connected to the wiring circuit 140 through the plurality of connection pads 130. The semiconductor package 10 may be connected to an external device through the plurality of connection bumps 400. Unlike the plurality of connection pads 130 which are distinguished into a first group of connection pads 130a having a first width W1 and a second group of connection pads 130b having a second width W2 depending on their positions, the plurality of connection bumps 400 may have the same size. At least some of the plurality of connection bumps 400 may be in contact with the protective layer 150. The plurality of connection bumps 400 may include, for example, tin (Sn) or an alloy (Sn—Ag—Cu) containing tin.

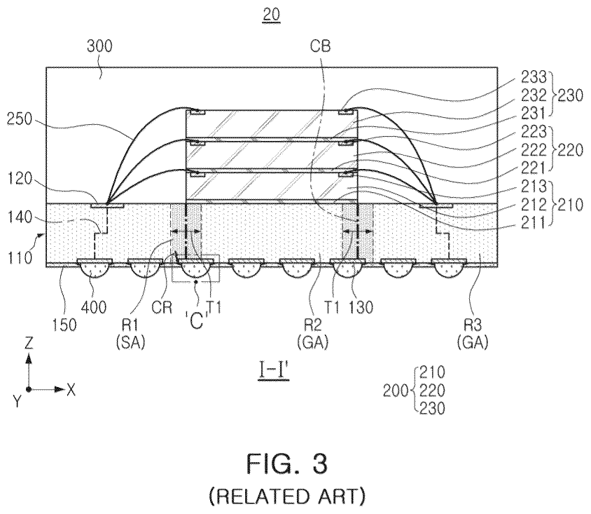

FIG. 3 is a cross-sectional view illustrating a semiconductor package 20 of the related art. FIG. 3 illustrates an area corresponding to the cross-sectional view of FIG. 1B.

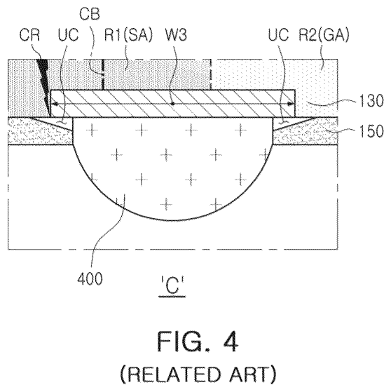

FIG. 4 is a partially enlarged view illustrating a portion of a semiconductor package 20 of the related art. FIG. 4 is an enlarged view of the ‘C’ area of FIG. 3.

FIG. 3 and FIG. 4 illustrate a problem of the related art, which may occur in the first region R1 evaluated as a vulnerable area SA, and which does not indicate that this is a known technology or a defect of the disclosure.

Referring to FIG. 3 and FIG. 4, in the semiconductor package 20, when the connection pads 130 overlapping the first region R1 evaluated as a vulnerable area SA are not formed to a sufficient size, an undercut UC may exist in the portion overlapping the first region R1, and a crack CR may occur due to stress aggravated by a plurality of semiconductor chips 200, a package substrate 110, a plurality of connection bumps 400, or the like. The connection pads 130 of the semiconductor package 20 may all have the same third width W3, and the reliability of the semiconductor package 20 may be reduced by an undercut UC that may be formed between the protective layer 150 and a crack CR that occurs in the package substrate 110.

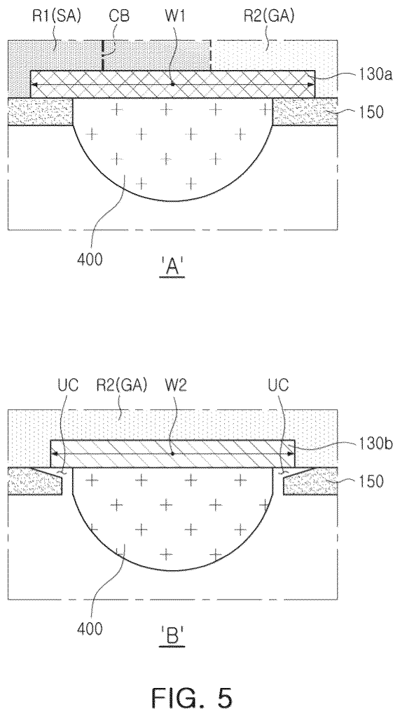

FIGS. 5 to 8 are partially enlarged views illustrating a portion of a semiconductor package according to an example embodiment. FIGS. 5 to 8 exemplarily show other embodiments of FIG. 2, which are enlarged views of the ‘A’ and ‘B’ regions of FIG. 1B.

Referring to FIG. 5, unlike the example embodiment of FIG. 2, the connection bump 400 below the second connection pad 130b where the undercut UC is formed may be spaced apart from the protective layer 150. A portion of the lower surface of the second connection pad 130b may be exposed. The connection bump 400 below the second connection pad 130b may be formed to contact the protective layer 150, and then, may be spaced apart as the process progresses. The connection bump 400 below the first connection pad 130a may be in contact with the protective layer 150 as in the example embodiment of FIG. 2.

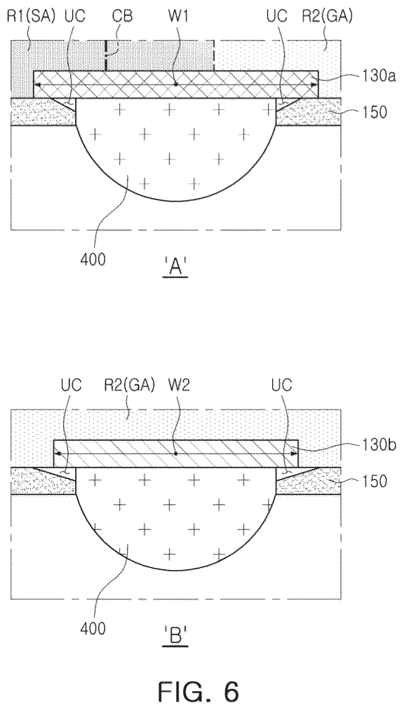

Referring to FIG. 6, unlike the example embodiment of FIG. 2, an undercut UC may also be formed under the first connection pad 130a. However, the size of the undercut UC formed under the first connection pad 130a may be smaller than the undercut UC formed under the second connection pad 130b. Unlike the example embodiment of FIG. 4, the undercut UC under the first connection pad 130a may not extend to the area between the package substrate 110 and the protective layer 150, but may be located only under the first connection pad 130a.

In the disclosure, the first connection pad 130a is formed with a first width W1 that is larger than the second width W2 of the second connection pad 130b, so that the formation of an undercut UC may be prevented, and even if an undercut UC is formed, it may be formed relatively smaller than the undercut formed under the second connection pad 130b.

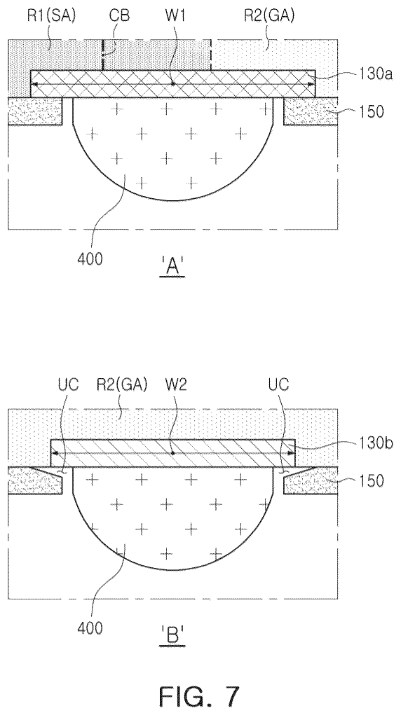

Referring to FIG. 7, unlike the example embodiment of FIG. 2, the connection bumps 400 may be spaced apart from the protective layer 150. Not only the connection bump 400 below the second connection pad 130b, but also the connection bump 400 below the first connection pads 130a may be spaced apart from the protective layer 150. The second connection pad 130b may have a larger exposed lower surface area than the first connection pad 130a due to the undercut UC. In an example embodiment, the connection bumps 400 and the protective layer 150 may be formed to be in contact with each other, and then, may be spaced apart as the process progresses. In an example embodiment, the connection bumps 400 and the protective layer 150 may be formed to be spaced apart from the beginning.

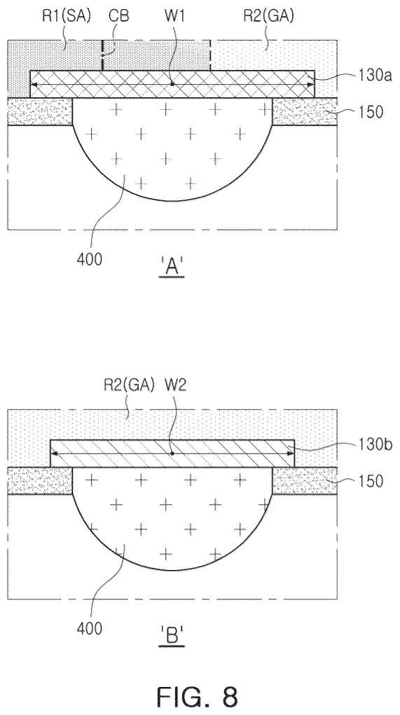

Referring to FIG. 8, unlike the example embodiment of FIG. 2, the undercut UC may not exist not only under the first connection pad 130a but also under the second connection pad 130b. A part of the lower surface of each of the first connection pad 130a and the second connection pad 130b may be in contact with the connection bump 400, and the remaining part may be in contact with the protective layer 150. The undercut UC is a configuration that may be formed during the process, but may not be formed as in the present embodiment.

The descriptions with reference to FIGS. 5 to 8 may be combined with each other within a compatible range. FIGS. 5 to 8 illustrate an example embodiment of the form of a plurality of connection pads 130 and a protective layer 150, and may be variously modified within a range that a person skilled in the art may change. The example embodiments described with reference to FIGS. 5 to 8 may be applied not only to the semiconductor package 10 of FIGS. 1A to 2, but also to embodiments described later.

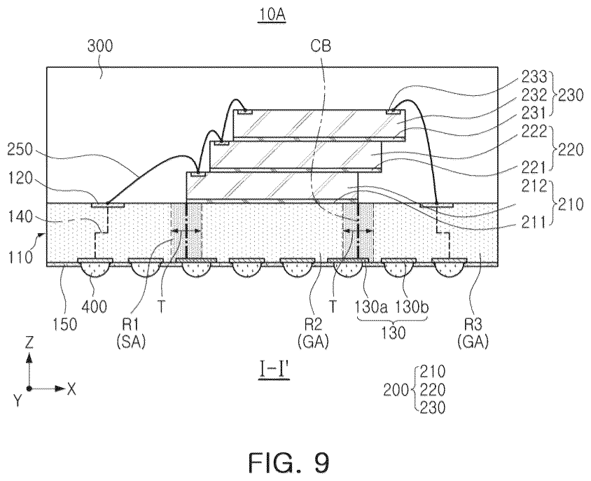

FIG. 9 is a cross-sectional view illustrating a semiconductor package 10A according to an example embodiment.

Referring to FIG. 9, unlike the semiconductor package 10 of FIG. 1B, in the semiconductor package 10A, a plurality of semiconductor chips 200 stacked in a vertical direction (for example, in the Z-direction) may be shifted in a horizontal direction (for example, in the X-direction or the Y-direction) and disposed. Depending on the arrangement form, at least one of the second semiconductor chip 220 and the third semiconductor chip 230 may also overlap with the third region R3. The direction, degree, and the like, in which the second semiconductor chip 220 and the third semiconductor chip 230 are shifted may be varied. Even when a plurality of semiconductor chips 200 are disposed to be shifted from each other, the contact boundary CB of the package substrate 110 and the first to third regions R1, R2 and R3 may be defined by the first semiconductor chip 210 at the bottom. Similar to the semiconductor package 10 of FIG. 1B, the contact boundary CB may be defined as a boundary that overlaps the edge of the contact surface of the first semiconductor chip 210 and the package substrate 110.

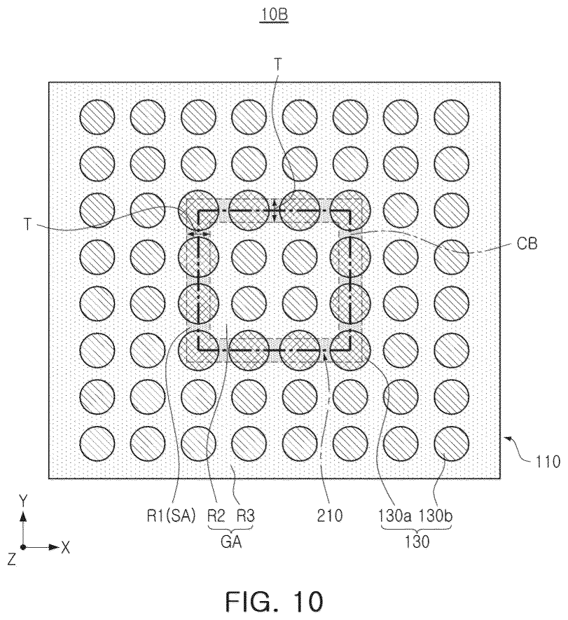

FIG. 10 is a plan view illustrating a semiconductor package 10B according to an example embodiment.

Referring to FIG. 10, unlike the semiconductor package 10A of FIG. 1A, in the semiconductor package 10B, at least some of the first group of the connection pads 130a may overlap not only the first region R1 but also the second region R2 and the third region R3. The width T of the first region R1 evaluated as the vulnerable area SA may be smaller than the width of the first group of the connection pads 130a.

Even when the width T of the first region R1 is smaller than the width of the first group of the connection pads 130a, in an example embodiment, the first group of the connection pads 130a may overlap with the first region R1 and the second region R2 but not overlap with the third region R3. In an example embodiment, the first group of the connection pads 130a may overlap with the first region R1 and the third region R3 but may not overlap with the second region R2.

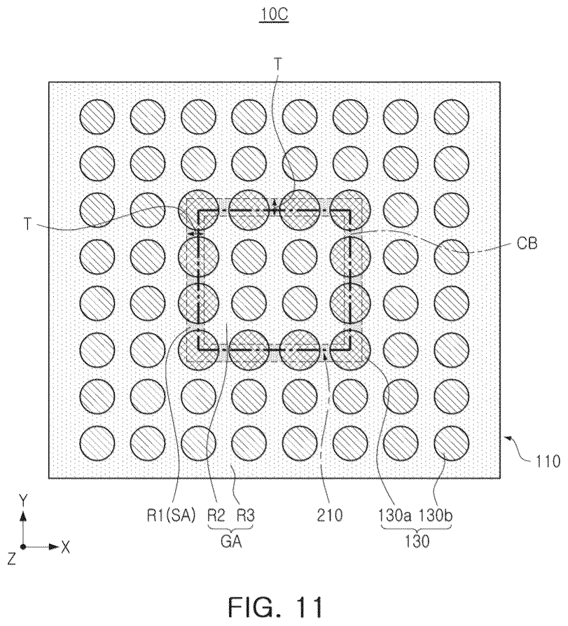

Referring to FIG. 11, unlike the semiconductor package 10B of FIG. 10, the contact boundary CB of the semiconductor package 10C may not be the center line of the first region R1. According to the example embodiment, the arrangement relationship between the first region R1 evaluated as the vulnerable area SA and the contact boundary CB may be modified. The inner side of the first region R1 may be formed with a narrower width than the outer side. In an example embodiment, as the width of the inner side of the first region R1 is narrowed, the contact boundary CB may actually become the boundary line between the first region R1 and the second region R2.

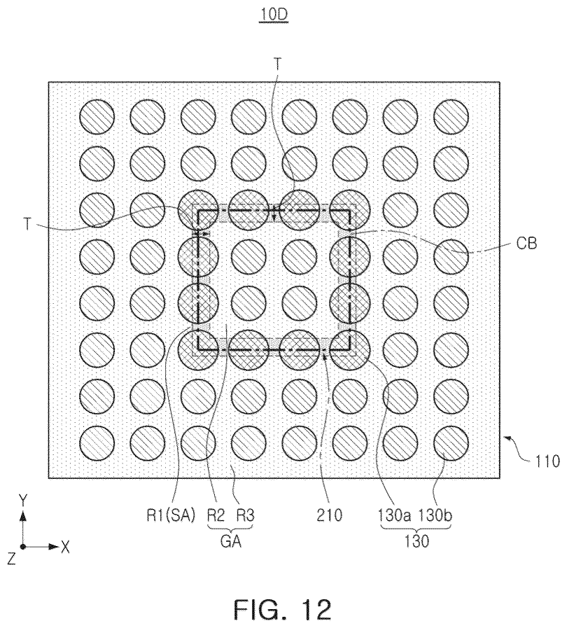

Referring to FIG. 12, unlike the semiconductor package 10C of FIG. 11, the semiconductor package 10D may be formed so that the outer side of the first region R1 has a narrower width than the inner side. In an example embodiment, as the width of the outer side of the first region R1 is narrowed, the contact boundary CB may actually become the boundary line between the first region R1 and the third region R3. As described with reference to FIGS. 11 and 12, the first region R1 may include the contact boundary CB, but the widths of the inner side and the outer side may be formed differently.

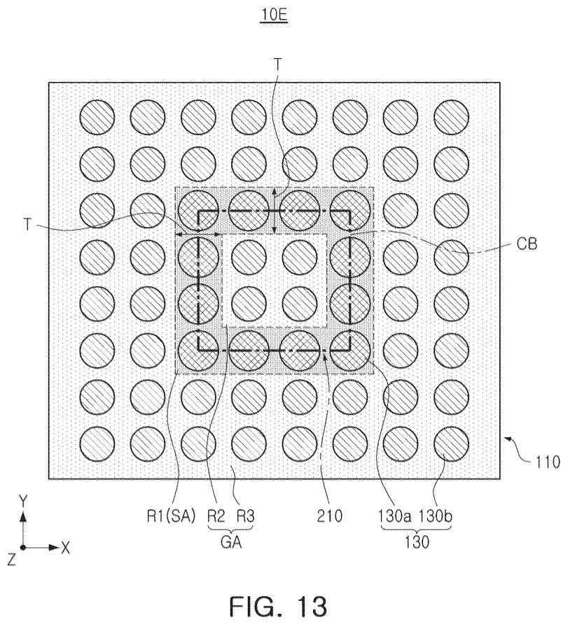

Referring to FIG. 13, unlike the semiconductor package 10B of FIG. 10, the semiconductor package 10E may be formed so that at least some of the first group of the connection pads 130a overlap with the first region R1, and may not overlap with the second region R2 and the third region R3. The width T of the first region R1 may be larger than the width of the first group of the connection pads 130a. In an example embodiment, as illustrated, at least some of the first group of the connection pads 130a may overlap the contact boundary CB. In an example embodiment, unlike illustrated, the width of the plurality of connection pads 130 may be smaller than illustrated, and the first group of the connection pads 130a may be disposed to overlap the first region R1 without overlapping the contact boundary CB.

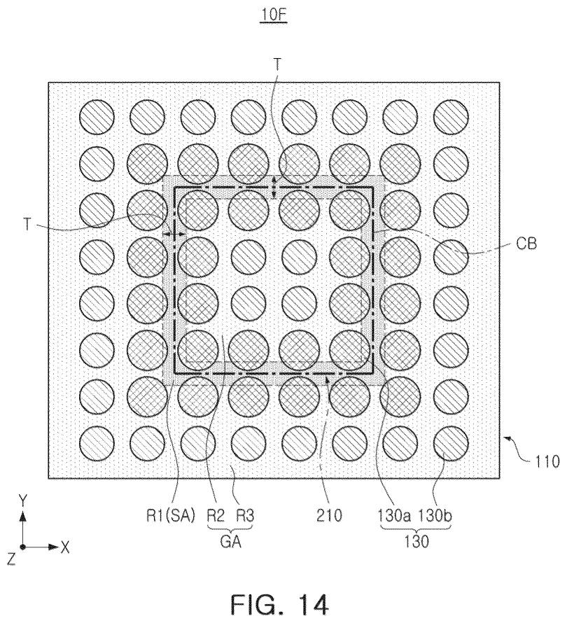

Referring to FIG. 14, unlike the semiconductor package 10 of FIG. 1A, the semiconductor package 10F may be disposed such that some of the first group of the connection pads 130a overlap the first region R1 and the third region R3, and other some of the first group of the connection pads 130a overlap the first region R1 and the second region R2. With respect to the contact boundary CB, the first group of the connection pads 130a may be disposed on both the inner and outer sides. At least some of the first group of the connection pads 130a may not overlap with the contact boundary CB.

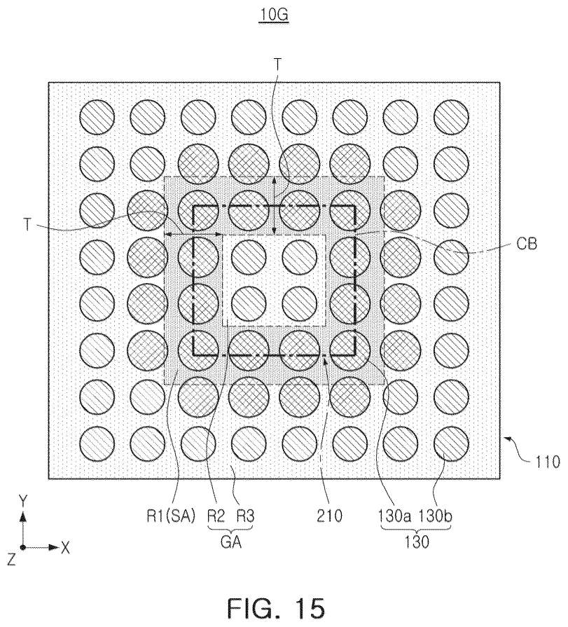

Referring to FIG. 15, unlike the semiconductor package 10F of FIG. 14, in the semiconductor package 10G, some of the first group of the connection pads 130a may overlap with the contact boundary CB, and the remaining some of the first group of the connection pads 130a may not overlap with the contact boundary CB. The first group of the connection pads 130a that overlap with the contact boundary CB may not overlap with the second region R2 and the third region R3. The first group of the connection pads 130a that do not overlap with the contact boundary CB may overlap with the third region R3. In an example embodiment, the four corners of the outer edge of the first region R1 may not overlap with the first group of connection pads 130a.

The description with reference to FIGS. 9 to 15 illustrates example embodiments of the first group of connection pads 130a overlapping the first region R1, and the arrangement relationship thereof may be modified within a range that a person skilled in the art may change. The compatible contents of the descriptions with reference to FIGS. 1A to 2 and FIGS. 5 to 12 may be variously combined or modified.

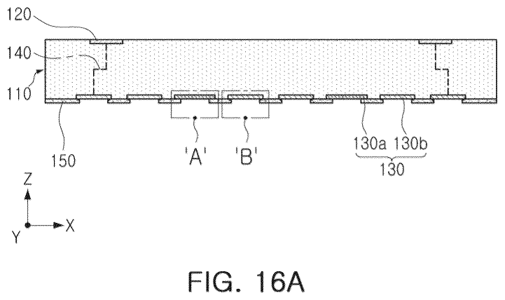

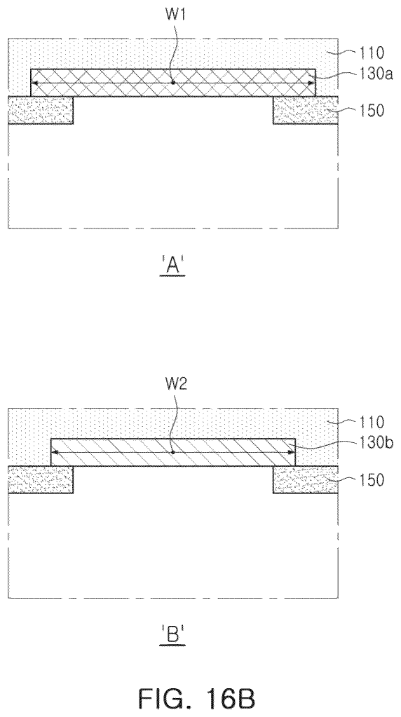

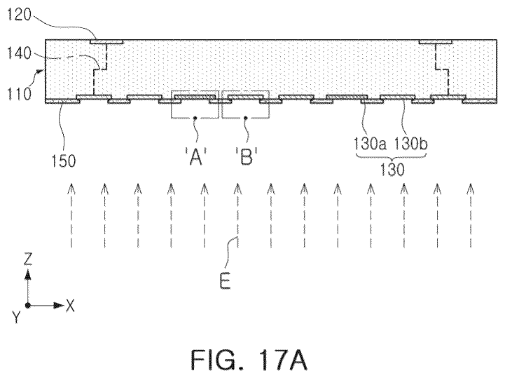

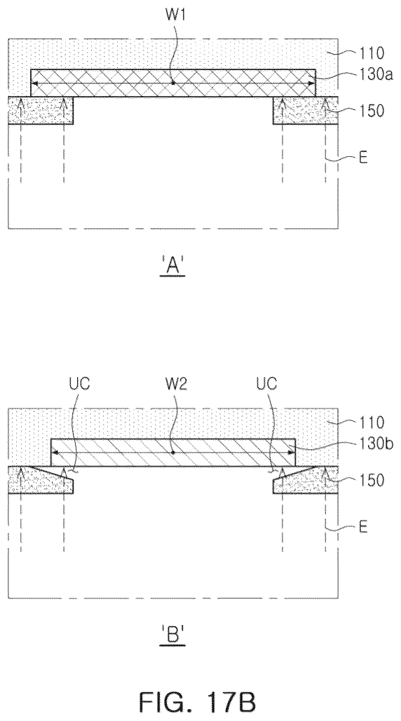

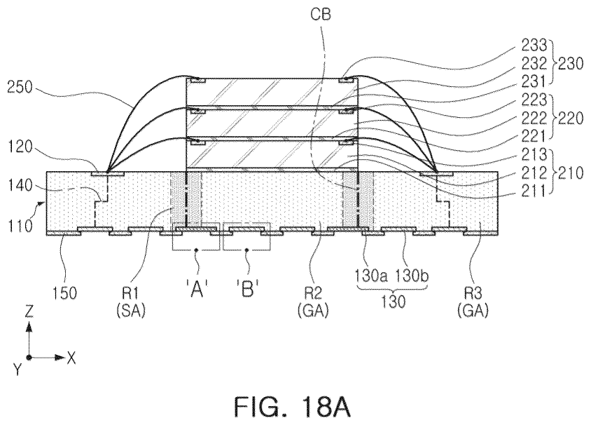

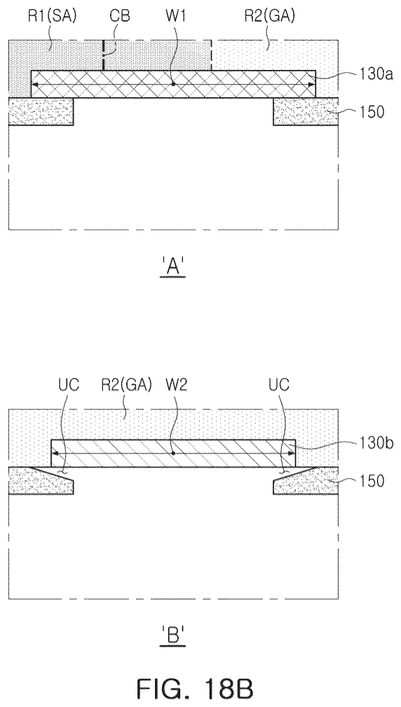

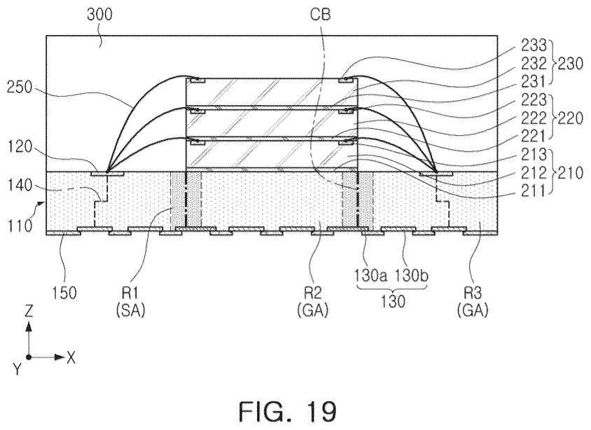

FIGS. 16A, 17A, 18A, and 19 are cross-sectional views illustrated according to the process order to explain a method of manufacturing a semiconductor package according to an example embodiment. FIGS. 16A, 17A, 18A, and 19 illustrate an embodiment of a method for manufacturing a semiconductor package 10 of FIG. 1B.

FIGS. 16B, 17B, and 18B are enlarged views of parts illustrated in the order of processes to explain a method for manufacturing a semiconductor package according to an example embodiment. FIGS. 13B, 14B, and 15B illustrate an embodiment of a method for manufacturing the ‘A’ region and the ‘B’ region of FIG. 2.

In the description of FIGS. 16A to 19, drawings with the same reference numerals are described as manufacturing processes that are performed simultaneously. For example, FIGS. 16A and 16B are drawings explaining the same manufacturing operations.

Referring to FIGS. 16A and 16B, a package substrate 110 on which upper pads 120, a plurality of connection pads 130, the wiring circuit 140, and a protective layer 150 are formed may be prepared.

In an example embodiment, depending on the type of the package substrate 110, conductive patterns and insulating layers may be repeatedly laminated within the package substrate 110, and conductive vias may be formed that penetrate the insulating layers and connect conductive patterns of different levels. A plurality of connection pads 130 may be formed on a lower surface of the package substrate 110. The plurality of connection pads 130 may include a first group of connection pads 130a having a first width W1 and a second group of connection pads 130b having a second width W2. The first width W1 may be larger than the second width W2. Referring to FIGS. 1A and 2 together, the first group of the connection pads 130a may be disposed at a position overlapping the first region R1 defined as the first semiconductor chip 210 is mounted in a subsequent process, and the second group of the connection pads 130b may be disposed at a position not overlapping the first region R1. In an example embodiment, the protective layer 150 may be formed by applying a composition material, for example, photo solder resist (PSR) ink and a curing agent, to cover the lower surface of the package substrate 110 and the lower surfaces of the plurality of connection pads 130, and then removing a portion of the applied composition material so that the lower surfaces of the plurality of connection pads 130 are exposed.

Referring to FIGS. 17A and 17B, an exposure process for curing the protective layer 150 may be performed.

The exposure process may be performed by, for example, irradiating the package substrate 110 with ultra violet (UV). In this operation, the bonding strength of the protective layer 150 with the package substrate 110 and the plurality of connection pads 130 may be strengthened. However, some of the second connection pads 130b among the second group of connection pads 130b having the second width W2 may have an undercut UC formed since the contact area with the protective layer 150 is not sufficiently secured. The first group of connection pads 130a having the first width W1 larger than the second width W2 may prevent the undercut UC or may be formed in a relatively small size even if the undercut UC is formed since the contact area with the protective layer 150 is sufficiently secured.

Referring to FIGS. 18A and 18B, a plurality of semiconductor chips 200 may be stacked on a package substrate 110 and connection wires 250 may be formed. As the first semiconductor chip 210 is mounted, the contact boundary CB of the package substrate 110 may be defined, and as the contact boundary CB is defined, the first to third regions R1, R2 and R3 may be defined. The first semiconductor chip 210 may be mounted at a position such that the first group of the connection pads 130a overlap with the first region R1, and the second group of the connection pads 130b do not overlap with the first region R1. The connection wires 250 may be formed to connect the respective connection pads 213, 223 and 233 of the plurality of semiconductor chips 200 and the upper pads 120.

In the process of stacking the plurality of semiconductor chips 200, the first region R1 may be evaluated as a vulnerable area SA due to increased stress. The disclosure has a feature of improving the reliability of a semiconductor package while securing the design freedom of a package substrate 110 by forming the first group of connection pads 130a overlapping the first region R1, which is a vulnerable area SA, with a first width W1 larger than the second width W2 of the second group of connection pads 130b that do not overlap the first region R1.

Referring to FIG. 19, an encapsulant 300 covering a plurality of semiconductor chips 200 and connection wires 250 may be formed on a package substrate 110.

The encapsulant 300 may be formed, for example, by applying and curing

EMC. The encapsulant 300 may be formed so that the upper surface is positioned at a higher level than that illustrated, and then the height of the upper surface may be adjusted through a flattening process. In an example embodiment, if the semiconductor package does not include a encapsulant 300, this process may be omitted.

Hereinafter, referring to FIGS. 1A to 2 together, a semiconductor package 10 may be manufactured by forming a plurality of connection bumps 400 below the lower surfaces of the plurality of connection pads 130, respectively. The plurality of connection bumps 400 may be formed by attaching ball-shaped solder to the plurality of connection pads 130 and then enhancing the bonding strength with the plurality of connection pads 130 through a process such as thermal compression. In this process, at least some of the plurality of connection bumps 400 may be in contact with the protective layer 150. As the plurality of connection bumps 400 are formed, stress may be further increased in the first region R1. The disclosure may prevent reliability degradation due to stress load by securing the first width W1 of the first group of connection pads 130a overlapping the first region R1.

As set forth above, according to example embodiments, a semiconductor package having improved reliability and design freedom may be provided by selectively increasing the width of connection pads overlapping a portion of a package substrate.

While example embodiments have been illustrated and described above, it will be apparent to those skilled in the art that modifications and variations could be made without departing from the scope of the disclosure as defined by the appended claims.

What is claimed is:

1. A semiconductor package comprising:
a plurality of semiconductor chips stacked vertically, and comprising a first semiconductor chip at a bottom in a vertical direction;
a package substrate below the plurality of semiconductor chips, and comprising:
a contact boundary defined by the first semiconductor chip, and
a first region that is a ring-shaped region extending along the contact boundary with a predetermined width,
a second region inside the first region,
and a third region outside the first region;
a plurality of connection pads on a lower surface of the package substrate; and
a plurality of connection bumps below the plurality of connection pads, respectively,
wherein the plurality of connection pads comprise:
a first group of connection pads at least a portion of each of which is within the first region, and
a second group of connection pads within the second region and the third region, and
wherein a first width of the first group of connection pads is greater than a second width of the second group of connection pads.

2. The semiconductor package of claim 1, wherein the contact boundary is provided as an edge boundary of a contact surface between the first semiconductor chip and the package substrate.

3. The semiconductor package of claim 1, wherein the second group of connection pads does not overlap with the first region.

4. The semiconductor package of claim 1, wherein at least some of the first group of connection pads overlap with the contact boundary.

5. The semiconductor package of claim 1, wherein at least some of the first group of connection pads overlap with the first region and the second region.

6. The semiconductor package of claim 1, wherein at least some of the first group of connection pads overlap with the first region and the third region.

7. The semiconductor package of claim 1, wherein the first width is about 1.05 to about 1.15 times the second width.

8. The semiconductor package of claim 1, wherein in a viewpoint parallel to an upper surface of the package substrate, the predetermined width of the first region comprises an inner side portion and an outer side portion based on the contact boundary, and
wherein a width of the inner side portion and a width of the outer side portion are substantially the same.

9. The semiconductor package of claim 7, wherein the predetermined width of the first region is about 150 μm to about 250 μm.

10. The semiconductor package of claim 1, wherein the first semiconductor chip further comprises connection pads on an upper surface of the first semiconductor chip,
wherein the package substrate further comprises upper pads on an upper surface of the package substrate, and
wherein the semiconductor package further comprises connection wires connecting the connection pads and the upper pads.

11. The semiconductor package of claim 1, wherein the plurality of semiconductor chips further comprise a second semiconductor chip stacked on the first semiconductor chip and a third semiconductor chip stacked on the second semiconductor chip.

12. The semiconductor package of claim 11, wherein the second semiconductor chip and the third semiconductor chip overlap the first region and the second region.

13. The semiconductor package of claim 11, wherein at least one of the second semiconductor chip and the third semiconductor chip overlaps the third region.

14. A semiconductor package comprising:
a semiconductor chip;
a package substrate below the semiconductor chip in a vertical direction; and
a plurality of connection pads on a lower surface of the package substrate,
wherein the plurality of connection pads comprise:
a first group of connection pads having a first width, and
a second group of connection pads having a second width smaller than the first width, and
wherein the first group of connection pads are closer to an edge boundary of a contact surface between the semiconductor chip and the package substrate than the second group of connection pads.

15. The semiconductor package of claim 14, wherein at least one of the first group of connection pads partially overlaps with the semiconductor chip in the vertical direction.

16. The semiconductor package of claim 14, wherein some connection pads of the second group of connection pads overlap with the semiconductor chip, and
wherein the other connection pads of the second group of connection pads do not overlap with the semiconductor chip.

17. A semiconductor package comprising:
a package substrate;
a semiconductor chip on the package substrate, in a vertical direction;
a plurality of connection pads on a lower surface of the package substrate, in the vertical direction;
a plurality of connection bumps below the plurality of connection pads, respectively; and
a protective layer covering at least portions of the plurality of connection pads and surrounding at least portions of the plurality of connection bumps,
wherein the plurality of connection pads comprise:
a first connection pad adjacent to an edge boundary of a contact surface between the semiconductor chip and the package substrate, and
a second connection pad around the first connection pad, and
wherein a first contact area between the first connection pad and the protective layer is larger than a second contact area between the second connection pad and the protective layer.

18. The semiconductor package of claim 17, further comprising an undercut extending in a direction horizontal to the lower surface of the package substrate, between the second connection pad and the protective layer,
wherein the undercut separates the second connection pad and the protective layer.

19. The semiconductor package of claim 17, further comprising undercuts extending in a horizontal direction to the lower surface of the package substrate, between the first connection pad and the protective layer and between the second connection pad and the protective layer,
wherein the undercuts separate the first connection pad and the second connection pad and the protective layer at least partly, and
wherein, among the undercuts, a first undercut positioned between the second connection pad and the protective layer has a greater length extending in the horizontal direction than a second undercut positioned between the first connection pad and the protective layer.

20. The semiconductor package of claim 17, wherein at least one of the plurality of connection bumps is in contact with the protective layer.
